(19) United States
(12) Patent Application Publication
(10) Pub. No.: US 2019/0033646 A1
(43) Pub. Date: Jan. 31, 2019

(54) TERMINAL CONNECTION STRUCTURE AND DISPLAY DEVICE

(71) Applicant: SHARP KABUSHIKI KAISHA, Sakai City, Osaka (JP)

(72) Inventors: Yukio SHIMIZU, Sakai City (JP); Motoji SHIOTA, Sakai City (JP); Keiji AOTA, Sakai City (JP)

(73) Assignee: Sharp Kabushiki Kaisha, Sakai City, Osaka (JP)

(21) Appl. No.: 16/071,620

(22) PCT Filed: Jan. 20, 2017
(86) PCT No.: PCT/JP2017/001859

§ 371 Date: Jul. 20, 2018

(30) Foreign Application Priority Data
Jan. 28, 2016 (JP) 2016-014162

(51) Int. Cl. G02F 1/1345; H01R 12/62; H05K 1/14; H05K 1/11

(52) U.S. Cl. CPC G02F 1/13452; H01R 12/62; H05K 1/147; H05K 1/118; H05K 2201/056; H05K 2201/10136; H05K 2201/041; G02F 1/13458; H05K 2201/10977

(57) ABSTRACT

A terminal connection structure includes a large panel-side terminal (a high resistance terminal) 28 having relatively high electric resistance, and a large flexible board-side terminal (a low resistance terminal) 30 having relatively low electric resistance and connected to the large panel-side terminal 28. The large flexible board-side terminal 30 includes separated large flexible board-side terminals (separated low resistance terminals) 30a that are arranged at intervals and have a width relatively larger in a distal end side portion 30a2 with respect to a basal end side portion 30a1.

### TECHNICAL FIELD

The present invention relates to a terminal connection structure and a display device.

### BACKGROUND ART

A display device including a connection structure for connecting a flexible printed circuit board to a display panel described in Patent Document 1 has been known as one example. In the display device described in Patent Document 1, the driver IC including a built-in charge pump power supply is mounted on the display panel. Among wirings connected to the driver IC, the width of the FPC mounting pad of connection wiring leading to the driver built-in power supply is greater than that of the pads of other wirings. In addition, a portion of terminal intervals of a terminal array of the FPC mounting pad is widened as compared with other terminal intervals so that a wiring path from the pad to the driver IC is shortened. Similar terminal widths and terminal intervals are adopted for the terminal on the side of flexible printed circuit board that is electrically connected to the FPC mounting pad by pressure bonding.

### RELATED ART DOCUMENT

### Patent Document

Patent Document 1: Japanese Patent No. 5505754

### Problem to be Solved by the Invention

The display device described in Patent Document 1 includes the FPC mounting pad having a width greater than the pad of other wirings. In such a configuration, the anisotropic conductive tape that is present between each pad and each terminal on the flexible printed circuit board side has unevenness in fluidity and the filling amount. Therefore, the connection status via the anisotropic conductive tape is unstable and a problem may be caused in connection reliability.

### Disclosure of the Present Invention

An object of the present invention is to keep high connection reliability.

### Means for Solving the Problem

A terminal connection structure according to first means of the present technology includes a high resistance terminal having relatively high electric resistance, and a low resistance terminal having relatively low electric resistance and connected to the high resistance terminal, and the low resistance terminal including separated low resistance terminals that are arranged at intervals and have a width relatively larger in a distal end side portion with respect to a basal end side portion.

According to such a configuration, if the high resistance terminal is connected to the separated low resistance terminals of the low resistance terminal, a current that is supplied to one of the high resistance terminal and the low resistance terminal flows to the other one of them. With the configuration of the low resistance terminal including the separated low resistance terminals, the connection reliability is higher compared to a known configuration that the pad and the terminal that are connected to each other are not separated.

A current flowing between the high resistance terminal and the low resistance terminal tends to flow through the low resistance terminal, which has relatively low electric resistance, for a longer time as possible. Specifically, if a current flows from the low resistance terminal side to the high resistance terminal side, the current amount flowing from the distal end side portion of the low resistance terminal to the high resistance terminal is greater than the current amount flowing from the basal end side portion of the low resistance terminal to the high resistance terminal. If a current flows from the high resistance terminal side to the low resistance terminal side, the current amount flowing from the basal end side portion of the high resistance terminal to the low resistance terminal is greater than the current amount flowing from the distal end side portion to the low resistance terminal. The width of the distal end side portion of the separated low resistance terminals of the low resistance terminal with respect to the basal end side potion is relatively larger. Namely, the portion through which greater amount of current flows has a relatively larger width. According to such a configuration, a current efficiently flows between the terminals and effective electric resistance related to the connection can be lowered. Accordingly, the connection reliability can be kept high and effective electric resistance related to the connection can be lowered.

Following configurations may be preferable for embodiments of the present technology according to the first means.

(1) The low resistance terminal may include a terminal connection portion that connects distal end side portions of adjacent separated low resistance terminals. According to such a configuration, the distal end side portions of the adjacent separated low resistance terminals are connected to each other by the terminal connection portion. Accordingly, the distal end side portion of the separated low resistance terminal with respect to the basal end side portion, that is a portion through which a greater amount of current flows, has a width that is increased at most such that the effective electric resistance related to the connection can be further lowered.

(2) The terminal connection portion may connect distal end portions of the distal end side portions of the adjacent separated low resistance terminals. The current amount is greatest at the distal end portion of the distal end side portion of the separated low resistance terminal and the distal end portions having the greatest current amount are connected by the terminal connection portion such that the effective electric resistance related to the connection can be further lowered.

(3) The terminal connection portion may connect portions of the distal end side portions of the adjacent separated low resistance terminals, and the portions are closer to a basal end side than distal end portions. A positioning error may be caused in the connection of the high resistance terminal and the separated low resistance terminals. In some cases, the distal end portion of the distal end side portion of the separated low resistance terminal may not contribute to the connection to the high resistance terminal. Even in such a case, the terminal connection portion connects the portions of the distal end side portions of the adjacent separated low resistance terminals and the portions of the distal end side portions are closer to the basal ends than the distal end portions, and according to such a configuration, effective electric resistance can be lowered.

(4) The distal end side portion of the separated low resistance terminals may have a width that increases from a basal end side toward a distal end side. The width of the distal end side portions of the separated low resistance terminal increases from the basal end side toward the distal end side or toward the portion having a greater amount of current flow. Therefore, effective electric resistance related to the connection can be further lowered.

(5) The low resistance terminal may be thicker than the high resistance terminal. According to such a configuration, the electric resistance of the low resistance terminal is preferably lowered. The low resistance terminal that is relatively thick includes the separated low resistance terminals. With such a configuration, the connection reliability is further improved compared to a configuration that only a relatively thin high resistance terminal has a separated structure.

(6) The terminal connection structure may further include a second high resistance terminal arranged adjacent to the high resistance terminal, and a second low resistance terminal arranged adjacent to the low resistance terminal and connected to the second high resistance terminal, and the second low resistance terminal having a width same as that of the separated low resistance terminal. According to such a configuration, the separated low resistance terminals and the second low resistance terminal have a same width. Therefore, the separated low resistance terminals and the second low resistance terminal can be collectively connected to the high resistance terminal and the second high resistance terminal and high connection reliability can be obtained.

A terminal connection structure according to second means includes a high resistance terminal having relatively high resistance and including at least separated high resistance terminals arranged at intervals, and a low resistance terminal having relatively low resistance and including at least separated low resistance terminals that are arranged at intervals and are connected to the separated high resistance terminals, and a width of a distal end side portion of the separated low resistance terminals with respect to a basal end side portion or a width of a basal end side portion of the separated high resistance terminals with respect to a distal end side portion is relatively large.

According to such a configuration, if the separated high resistance terminals of the high resistance terminal are connected to the separated low resistance terminals of the low resistance terminal, a current that is supplied to one of the high resistance terminal and the low resistance terminal flows to the other one of them. With the configuration of the high resistance terminal including the separated high resistance terminals and the low resistance terminal including the separated low resistance terminals, the connection reliability is higher compared to a known configuration that the pad and the terminal that are connected to each other are not separated.

A current flowing between the high resistance terminal and the low resistance terminal tends to flow through the low resistance terminal, which has relatively low electric resistance, for a longer time as possible. Specifically, if a current flows from the low resistance terminal side to the high resistance terminal side, the current amount flowing from the distal end side portion of the low resistance terminal to the high resistance terminal is greater than the current amount flowing from the basal end side portion to the high resistance terminal. If a current flows from the high resistance terminal side to the low resistance terminal side, the current amount flowing from the basal end side portion of the high resistance terminal to the low resistance terminal is greater than the current amount flowing from the distal end side portion to the low resistance terminal. One of the width of the distal end side portion of the separated low resistance terminals of the low resistance terminal with respect to the basal end side potion and the width of the basal end side portion of the separated high resistance terminals of the high resistance terminal with respect to the distal end side portion is relatively larger. Namely, one of the portions through which greater amount of current flows has a relatively larger width. According to such a configuration, a current efficiently flows between the terminals and effective electric resistance related to the connection can be lowered. Accordingly, the connection reliability can be kept high and effective electric resistance related to the connection can be lowered.

Next, to solve the above problem, a display device according to the present technology includes the terminal connection structure, a display panel including the high resistance terminal, and a mounting component including the low resistance terminal and mounted on the display panel. According to the display device having such a configuration, the connection reliability of the mounting component to the display panel is high and the connection resistance is lowered such that high display quality can be stably obtained.

### Advantageous Effect of the Invention

According to the present invention, high connection reliability can be kept.

### BRIEF DESCRIPTION OF THE DRAWINGS

FIG. 1 is a general plan view illustrating a connection structure of a liquid crystal panel including a driver, a flexible printed circuit board, and a control circuit board according to a first embodiment of the present invention.

FIG. 2 is a general cross-sectional view illustrating a cross-sectional configuration of a liquid crystal display device taken along a long-side direction thereof.

FIG. 3 is a cross-sectional view illustrating a cross-sectional configuration of a display part of the liquid crystal panel.

FIG. 4 is an enlarged plan view illustrating a mounting area in an array board of the liquid crystal panel where the driver and the flexible printed circuit board are mounted.

FIG. 5 is a general cross-sectional view illustrating a cross-sectional configuration of a terminal connection structure of the liquid crystal panel, the driver, and the flexible printed circuit board.

FIG. 6 is a bottom view of one edge portion of the flexible printed circuit board.

FIG. 7 is a plan view illustrating the terminal connection structure before the flexible printed circuit board is connected to the array board of the liquid crystal panel.

FIG. 8 is a horizontal cross-sectional view illustrating the terminal connection structure where the flexible printed circuit board is connected to the array board of the liquid crystal panel.

FIG. 9 is a cross-sectional view taken along line ix-ix in FIG. 8.

FIG. 10 is a cross-sectional view taken along line x-x in FIG. 8.

FIG. 11 is a cross-sectional view taken along line xi-xi in FIG. 8.

FIG. 12 is a horizontal cross-sectional view illustrating a terminal connection structure where a flexible printed circuit board is connected to an array board of a liquid crystal panel according to a second embodiment of the present invention.

FIG. 13 is a horizontal cross-sectional view illustrating a terminal connection structure where a flexible printed circuit board is connected to an array board of a liquid crystal panel according to a third embodiment of the present invention.

FIG. 14 is a horizontal cross-sectional view illustrating a terminal connection structure where a flexible printed circuit board is connected to an array board of a liquid crystal panel according to a fourth embodiment of the present invention.

FIG. 15 is a horizontal cross-sectional view illustrating a terminal connection structure where a flexible printed circuit board is connected to an array board of a liquid crystal panel according to a fifth embodiment of the present invention.

FIG. 16 is a horizontal cross-sectional view illustrating a terminal connection structure where a flexible printed circuit board is connected to an array board of a liquid crystal panel according to a sixth embodiment of the present invention.

FIG. 17 is a horizontal cross-sectional view illustrating a terminal connection structure where a flexible printed circuit board is connected to an array board of a liquid crystal panel according to a seventh embodiment of the present invention.

FIG. 18 is a horizontal cross-sectional view illustrating a terminal connection structure where a flexible printed circuit board is connected to an array board of a liquid crystal panel according to an eighth embodiment of the present invention.

FIG. 19 is a horizontal cross-sectional view illustrating a terminal connection structure where a flexible printed circuit board is connected to an array board of a liquid crystal panel according to a ninth embodiment of the present invention.

FIG. 20 is a cross-sectional view taken along line xx-xx in FIG. 19.

### MODES FOR CARRYING OUT THE INVENTION

### First Embodiment

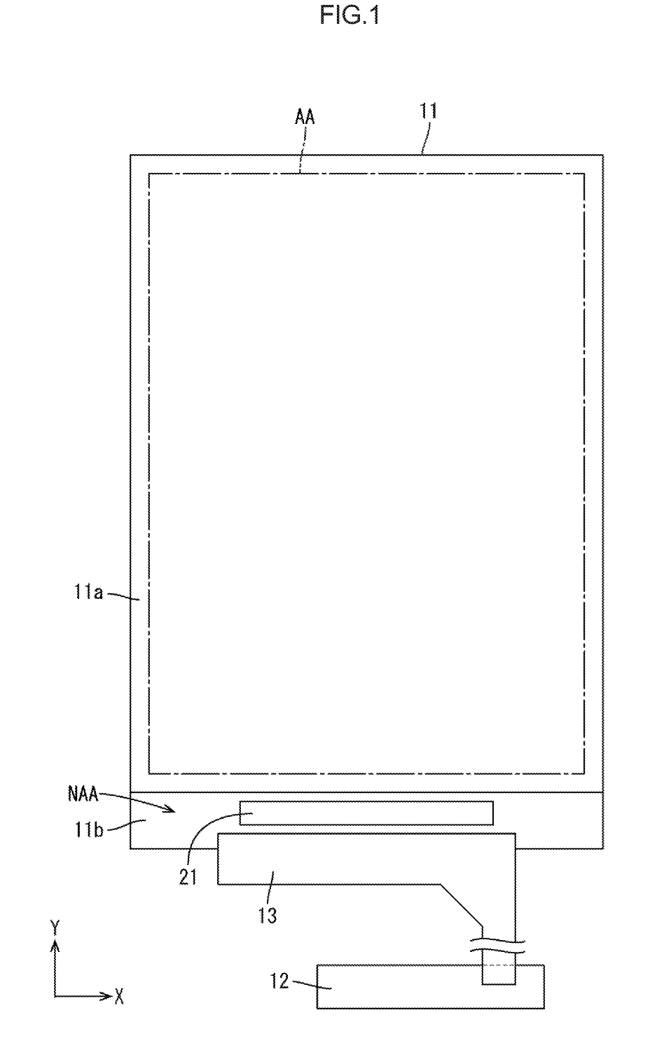

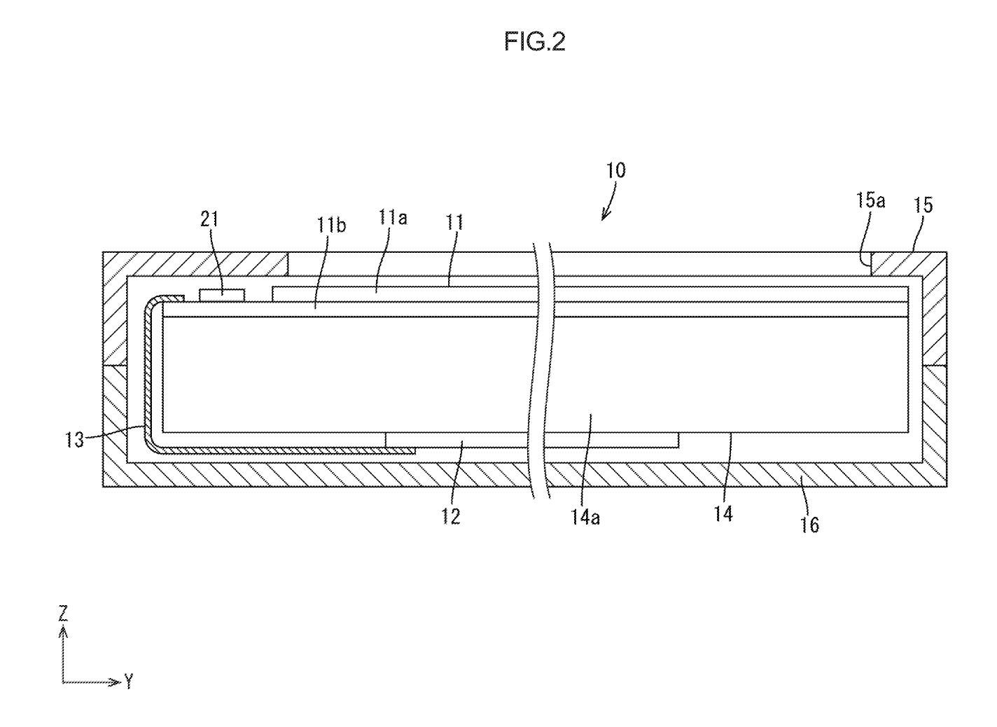

A first embodiment of the present technology will be described with reference to FIGS. 1 to 11. In this embodiment, a terminal connection structure of a liquid crystal panel 11 included in a liquid crystal display device 10 and a flexible printed circuit board 13 will be described as an example. X-axis, Y-axis and Z-axis may be present in the drawings and each of the axial directions represents a direction represented in each drawing. A vertical direction is referred to FIG. 2 and an upper side and a lower side in FIG. 2 correspond to a front side and a back side, respectively.

As illustrated in FIGS. 1 and 2, the liquid crystal display device 10 includes a liquid crystal panel (display panel) 11, a driver (a panel driving section, a mounting component) 21 driving the liquid crystal panel, a control circuit board (an external signal supply source) 12 supplying various kinds of input signals from outside to the liquid crystal panel 11 including the driver 21, the flexible printed circuit board (the mounting component) 13 electrically connecting the liquid crystal panel 11 and the external control circuit board 12, a backlight device (a lighting device) 14 that is an external light source supplying light to the liquid crystal panel 11. The liquid crystal display device 10 further includes a pair of front and rear exterior members 15, 16 to hold the liquid crystal panel 11 and the backlight device 14 that are attached together. The front exterior member 15 has an opening hole 15a through which images displayed on the liquid crystal panel 11 can be seen from outside.

Next, a configuration of the backlight device 14 will be briefly described. As illustrated in FIG. 2, the backlight device 14 includes a chassis 14a that has a substantially box shape opening toward the front side (toward the liquid crystal panel 11), a light source (such as cold cathode tubes, LEDs, organic EL, not illustrated) arranged within the chassis 14a, and an optical member (not illustrated) arranged to cover an opening hole of the chassis 14a. The optical member is configured to convert light rays from the light source into planar light.

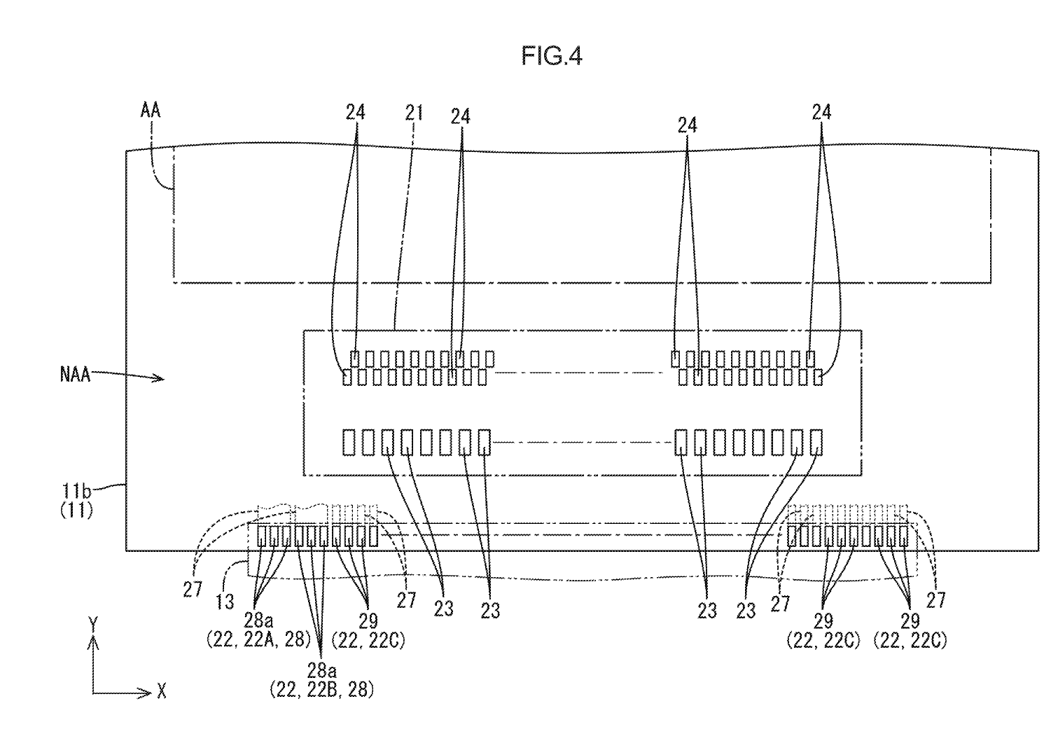

The liquid crystal panel 11 will be described. As illustrated in FIG. 1, the liquid crystal panel 11 has a vertically-long square (rectangular) shape as a whole. The liquid crystal panel 11 includes a display section (an active area, a display area) AA that is off centered toward one of ends of a short dimension thereof (the upper side in FIG. 1). The driver 21 and the flexible printed circuit board 13 are arranged at the other end of the short dimension of the liquid crystal panel 11 (the lower side in FIG. 1). An area of the liquid crystal panel 11 outside the display section AA is a non-display section (non-active area, a non-display area) NAA in which images are not displayed. A short-side direction and a long-side direction of the liquid crystal panel 11 correspond to the X-axis direction and the Y-axis direction in each drawing. In FIGS. 1 and 4, a chain line box slightly smaller than a CF substrate 11a indicates an outline of the display section AA. An area outside the chain line is the non-display section NAA.

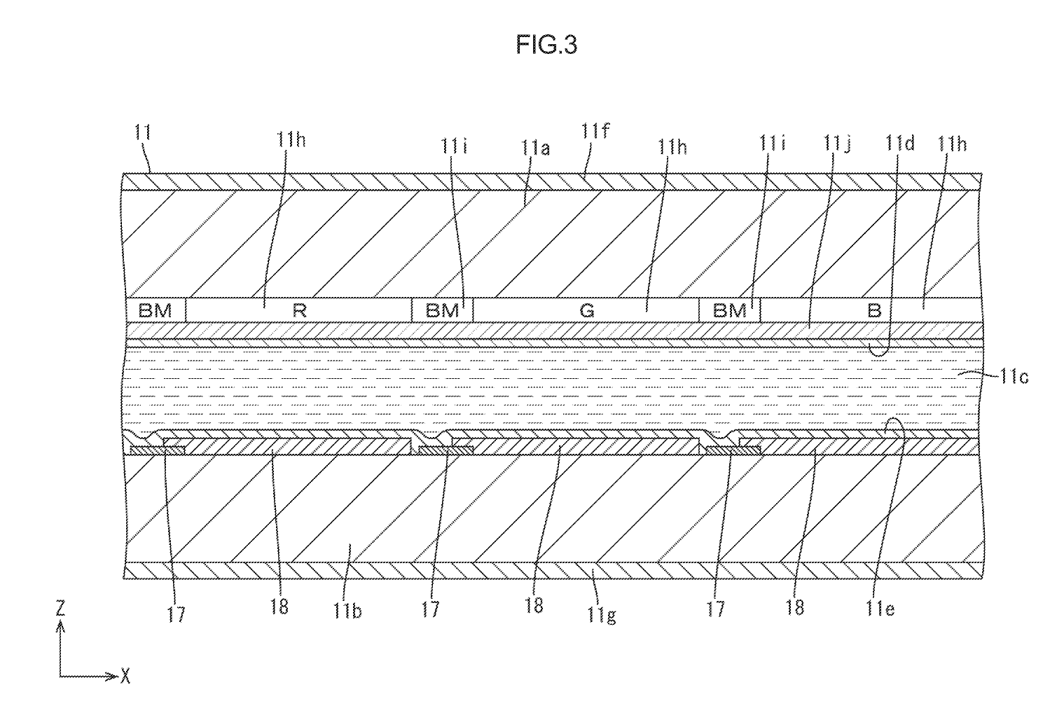

As illustrated in FIG. 3, the liquid crystal panel includes a pair of transparent substrates (having high transmissivity) 11a and 11b, and a liquid crystal layer 11c between the substrates 11a and 11b. The liquid crystal layer 11c includes liquid crystal molecules having optical characteristics that vary according to application of electric field. The substrates 11a and 11b are bonded together with a sealing agent, which is not illustrated, with a gap therebetween. The substrates 11a, 11b include a CF substrate (an opposing substrate) on the front and an array substrate (an active matrix substrate, a component substrate) 11b on a back side. Polarizing plates 11f and 11g are bonded to outer surfaces of the substrates 11a and 11b, respectively. As illustrated in FIG. 1, one of the short side edges of the peripheral edge portion of the array substrate 11b projects outside from the short side edge of the CF substrate 11a. The projected portion has amounting area where the driver 21 and the flexible printed circuit board 13 are mounted.

Next, a configuration on the array substrate 11b and the CF substrate 11a in the display section AA will be described briefly. As illustrated in FIG. 3, a number of the TFTs (thin film transistors) 17 that are switching components and a number of pixel electrodes 18 are arranged in a matrix on the inner surface of the array substrate 11b (the liquid crystal layer 11c side, the opposed surface side opposed to the CF substrate 11a). Furthermore, the gate lines and the source lines (both not illustrated) are arranged in a grid to surround the TFTs 17 and the pixel electrodes 18. Namely, the TFTs 17 and the pixel electrodes 18 are arranged at the respective intersections of the gate lines and the source lines in a grid. The gate lines and the source lines are connected to gate electrodes and source electrodes of the TFTs 17, respectively. The pixel electrodes 18 are connected to drain electrodes of the TFTs 17. Each of the pixel electrodes 18 has a vertically long rectangular shape in a plan view. The pixel electrodes 18 are made of transparent electrode material such as indium tin oxide (ITO) and zinc oxide (ZnO). Capacitor lines (not illustrated) that extend parallel to the gate lines and cross the pixel electrodes 18 may be disposed on the array substrate 11b. Color filters 11h are formed on the CF substrate 11a. The color filters 11h include red (R), green (G), and blue (B) color portions that are arranged in a matrix to overlap the pixel electrodes 18 on the array substrate 11b in a plan view. A light blocking layer 11i having a grid shape (a black matrix) is formed between the color portions included in the color filters 11h for reducing color mixture. The light blocking layer 11i is arranged to overlap the gate lines and the source lines in a plan view. A counter electrode 11j is formed in a solid pattern on surfaces of the color filters 11h and the light blocking layer 11i. The counter electrode 11j is opposed to the pixel electrodes 18 on the array substrate 11b. Alignment films 11d and 11e are formed on inner surfaces of the substrates 11a and 11b, respectively, for aligning the liquid crystal molecules included in the liquid crystal layer 11c.

The components connected to the liquid crystal panel 11 will be described. As illustrated in FIGS. 1 and 2, the control circuit board 12 is attached on the back surface of the chassis 14a of the backlight device 14 with a screw or other fixing member. The control circuit board 12 includes a substrate made of paper phenol or glass epoxy resin and electronic components mounted on the substrate for supplying various kinds of input signals to the driver 21. The control circuit board 12 further includes predetermined traces (conductive lines), which are not illustrated, routed on the substrate. One of ends of the flexible printed circuit board 13 is connected to the control circuit board 12.

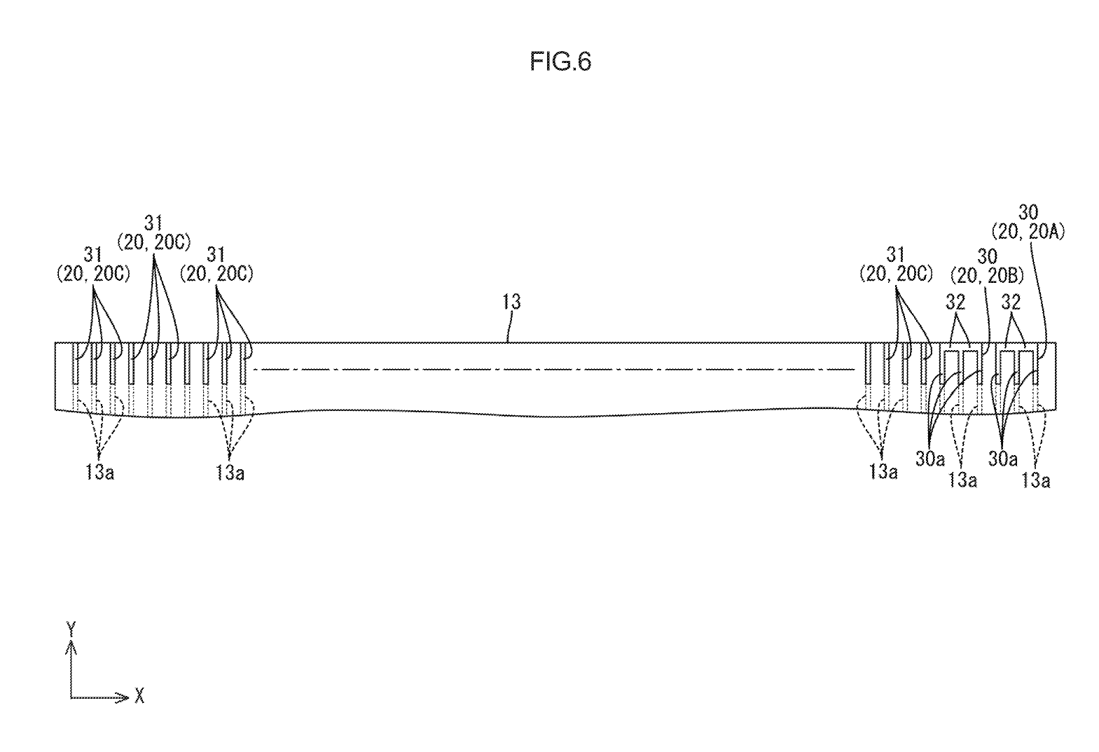

As illustrated in FIG. 6, the flexible printed circuit board 13 includes a base member made of synthetic resin (e.g., polyimide resin) having an insulating property and flexibility, and the flexible printed circuit board 13 includes traces on the base member. As illustrated in FIG. 2, the flexible printed circuit board 13 is folded within the liquid crystal display device 10 such that a shape in a cross-sectional view is a U-like shape. One of ends of the flexible printed circuit board 13 with respect to the length direction thereof is connected to the control circuit board 12 and the other end of the flexible printed circuit board 13 is connected to the array substrate 11b. The flexible printed circuit board 13 is mounted on the array substrate 11b of the liquid crystal panel 11 with the film on glass (FOG) mounting method. The ends of the flexible printed circuit board 13 with respect to the length direction include exposed portions of a trace pattern 13a which form terminals. The terminals are electrically connected to the control circuit board 12 and the array substrate 11b. A flexible board side terminal (a mounting component-side terminal) that is connected to the liquid crystal panel 11 will be described in detail later. The input signals supplied from the control circuit board 12 can be transmitted to the liquid crystal panel 11.

As illustrated in FIG. 1, the driver 21 includes an LSI chip including a driver circuit therein. The driver 21 operates according to signals supplied by the control circuit board 12, which is a signal source, processes the input signals supplied by the control circuit board 12 and generates output signals, and sends the output signals to the display section AA of the liquid crystal panel 11. The driver 21 has a horizontally long rectangular shape in the plan view. The driver 21 is orientated such that a long-side direction thereof is along the short side of the liquid crystal panel 11. The driver 21 is directly mounted on the array substrate 11b with the chip on glass (COG) mounting technology.

Next, a terminal connection structure of the flexible printed circuit board 13 and the driver 21 that are connected to the non-display section NAA of the array substrate 11b will be described. The non-display section NAA of the array substrate 11b includes a non-overlapping portion that does not overlap the CF substrate 11a. As illustrated in FIG. 1, the non-overlapping portion includes a driver 21 mounting area that is relatively near the display section AA and a flexible printed circuit board 13 mounting area that sandwiches the driver 21 mounting area with the display section AA. As illustrated in FIG. 4, in the flexible printed circuit board 13 mounting area of the array substrate 11b, flexible board panel-side terminals (panel-side terminals) 22 are arranged at intervals in the X-axis direction. The flexible board panel-side terminals 22 receive the input signals and power supply from the flexible printed circuit board 13. In the driver 21 mounting area of the array substrate 11b, the panel-side output terminals 23 are arranged at intervals in the X-axis direction and panel-side input terminals 24 are arranged at intervals in the X-axis direction. The panel-side output terminals 23 output signals to the driver 21 and the signals from the driver 21 are input to the panel-side input terminals 24. The flexible board panel-side terminals 22, the panel-side output terminals 23, and the panel-side input terminals 24 are arranged at predetermined intervals in the Y-axis direction. The flexible board panel-side terminals 22, the panel-side output terminals 23, and the panel-side input terminals 24 are made of a metal film same as the gate lines or the source lines and are surfaces thereof are covered with the transparent electrode material such as ITO or ZnO similarly to the pixel electrodes 18. Apart of each flexible board panel-side terminal 22 and each panel-side output terminal 23 are electrically connected to each other by a connection line 27 that is disposed on the non-display section NAA to cross a section between the flexible printed circuit board 13 mounting area and the driver 21 mounting area 21. In FIG. 4, the flexible printed circuit board 13 and the driver 21 are illustrated with a two-dot chain line.

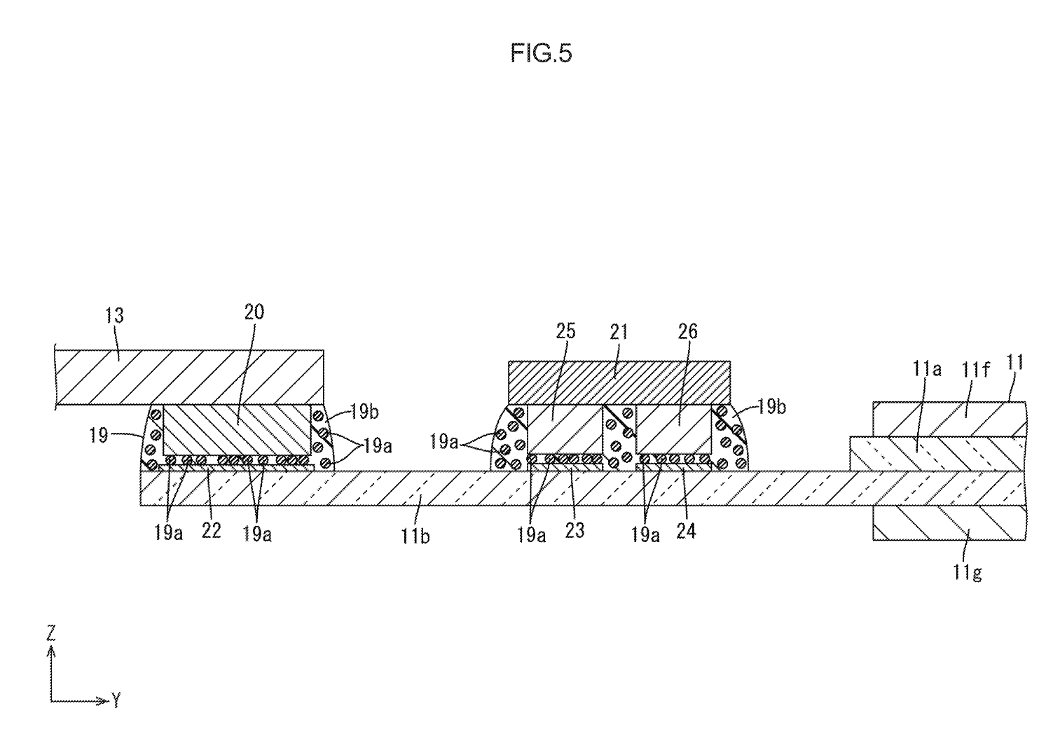

As illustrated in FIG. 5, on one edge portion of the flexible printed circuit board 13, flexible board-side terminals that are electrically connected to the flexible board panel-side terminals 22 are arranged at intervals in the X-axis direction. Driver-side input terminals 25 and driver-side output terminals 26 are arranged at intervals in the X-axis direction on the driver 21, respectively. The driver-side input terminals 25 are electrically connected to the panel-side output terminals 23 and the driver-side output terminals 26 are electrically connected to the panel-side input terminals 24. An anisotropic conductive film (ACF) 19 is present between the array substrate 11b of the liquid crystal panel 11 and each of the flexible printed circuit board 13 and the driver 21. The anisotropic conductive film 19 includes the conductive particles 19a and binder 19b in which the conductive particles 19a are dispersed. The terminals 22-24 on the liquid crystal panel 11 side are electrically connected to the terminals 20 on the flexible printed circuit board 13 and the terminals 25, 26 on the driver 21 via the conductive particles 19a. The terminal connection structure of the flexible printed circuit board 13 will be described in detail.

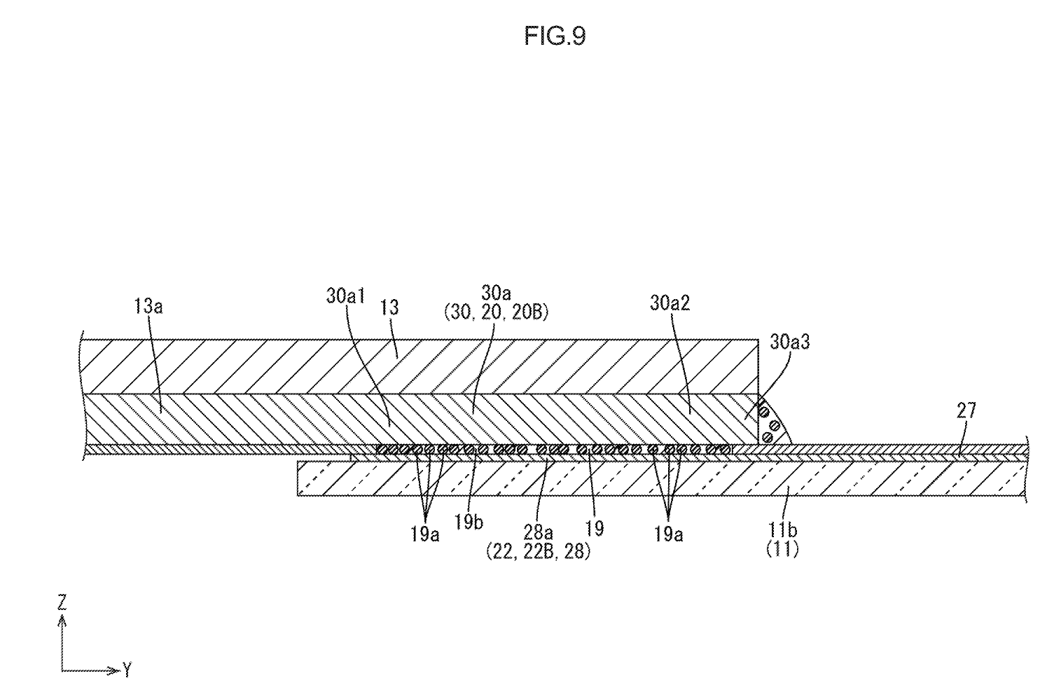

As illustrated in FIGS. 5 and 9, the flexible board panel-side terminals 22 is made of metal material having relatively higher electrical resistivity than the flexible board-side terminals 20 (such as aluminum) and has a thickness relatively smaller than that of the flexible board-side terminals 20. Namely, the flexible board panel-side terminals 22 have relatively high electric resistance. The flexible board panel-side terminals 22 have electrical resistivity of approximately 2.65×10⁻⁸ Ω·m and have a thickness of approximately 1 μm or less. The flexible board-side terminals 20 are made of metal material having lower electrical resistivity than the flexible board panel-side terminals 22 (such as copper) and have a thickness relatively greater than that of the flexible board panel-side terminals 22. Namely, the flexible board-side terminals 20 have relatively low electric resistance. The flexible board-side terminals 20 have electrical resistivity of approximately 1.65×10⁻⁸ Ωm and have a thickness of approximately 12 μm. The thickness of the flexible board-side terminals 20 is 10 times of that of the flexible board panel-side terminals 22 or more. In such a configuration, current flowing between the flexible board-side terminals 20 and the flexible board panel-side terminals 22 tends to flow for a longer time as possible through the flexible board-side terminals 20 having relatively low electric resistance. Specifically, in this embodiment, the current flows from the flexible board-side terminals 20 that are a current supply source side to the flexible board panel-side terminals 22 that are a current supplied side. Therefore, the flexible board-side terminals 20 have a greater amount of current flowing to the flexible board panel-side terminals 22 from a distal end portion thereof that is on the current supplied side (a lower stream side) than from a basal end portion thereof that is on the current supply source side (an upstream side).

As illustrated in FIG. 4, the flexible board panel-side terminals 22 at least include a power source panel-side terminal 22A for transmitting driving power for driving the liquid crystal panel 11, a ground panel-side terminal 22B for transmitting a ground potential (a common potential), and signal panel-side terminals 22C for transmitting various kinds of signals such as scanning signals supplied to the gate lines, image signals (data signals) supplied to the source lines, and other control signals. Among the terminals, the power source panel-side terminal 22A and the ground panel-side terminal 22B have a common structure and are formed from a large panel-side terminal (a high resistance terminal) 28 having a relatively large width. The signal panel-side terminals 22C are formed from a small panel-side terminal (a second high resistance terminal) 29 having a small width. Similarly, as illustrated in FIG. 6, the flexible board-side terminals 20 at least include a power source flexible board-side terminal 20A for transmitting driving power, a ground flexible board-side terminal 20B for transmitting a ground potential, and signal flexible board-side terminals 20C for transmitting various kinds of signals. Among the terminals, the power source flexible board-side terminal 20A and the ground flexible board-side terminal 20B have a common structure and are formed from a large flexible board-side terminal (a low resistance terminal) 30 having a relatively large width. The signal flexible board-side terminals 20C are formed from a small flexible board-side terminal (a second low resistance terminal) 31 having a relatively small width. A relatively large current flows through the large panel-side terminal 28 and the large flexible board-side terminal 30 and a relatively small and weak current flows through the small panel-side terminal 29 and the small flexible board-side terminal 31. Among the terminals, the large panel-side terminal 28 and the large flexible board-side terminal 30 are likely to be required to effectively reduce effective electric resistance related to electric connection according to progress of high precision, high function, and high speed operation of the liquid crystal panel 11.

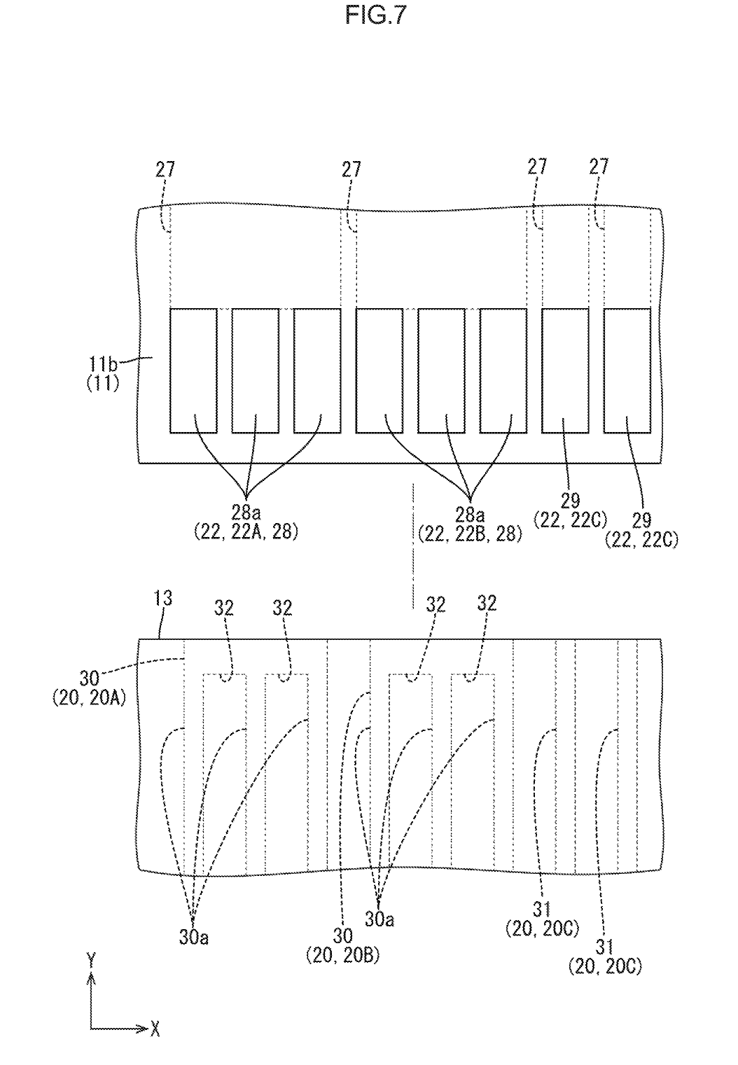

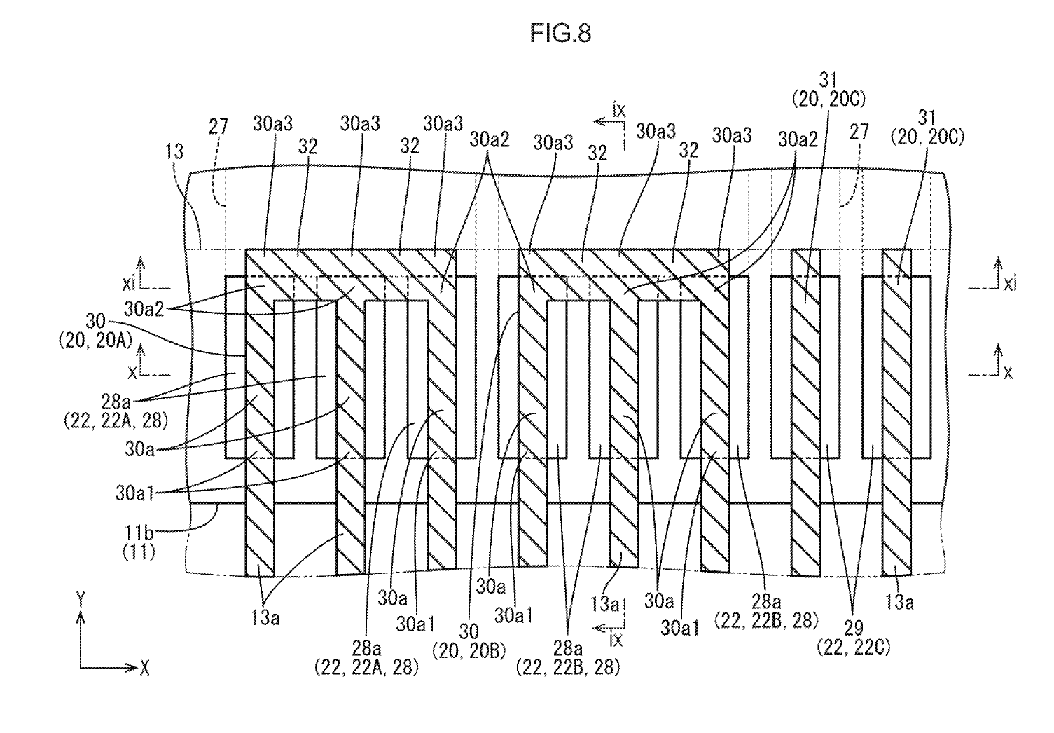

As illustrated in FIG. 7, the large panel-side terminal 28 includes three (multiple) separated large panel-side terminals (separated high resistance terminals) 28a and the large flexible board-side terminal 30 includes three (multiple) separated large flexible board-side terminals (separated low resistance terminals) 30a. The separated large panel-side terminal 28a has a width dimension substantially equal to that of the small panel-side terminal 29. An interval between adjacent separated large panel-side terminals 28a and an interval between the separated large panel-side terminal 28a and the small panel-side terminal 29 are substantially equal to an interval between adjacent small panel-side terminals 29. The three separated large panel-side terminals 28a of the large panel-side terminal 28 are overlapped with a connection line 27 (illustrated with a dot line in FIG. 7) having a width substantially equal to that of the large panel-side terminal 28. The separated large flexible board-side terminal 30a has a width dimension that is substantially equal to a width dimension of the small flexible board-side terminal 31. An interval between the adjacent separated large flexible board-side terminals 30a or an interval between the separated large flexible board-side terminal 30a and the small flexible board-side terminal 31 is substantially equal to an interval between adjacent small flexible board-side terminals 31. According to such a configuration, as illustrated in FIGS. 8 to 10, the three separated large panel-side terminals 28a of the large panel-side terminal 28 and the three separated large flexible board-side terminals 30a of the large flexible board-side terminal 30 are connected to each other via the anisotropic conductive film 19. If a current is supplied to each of the separated large flexible board-side terminals 30a, the current flows to each of the separated large panel-side terminals 28a. In a prior art configuration that each pad and each terminal is not separated, the anisotropic conductive film that is present between each pad and each terminal has unevenness in fluidity and the filling amount and connection status may be unstable. In the above-described separation structure of the large panel-side terminal 28 and the large flexible board-side terminal 30, the anisotropic conductive film 19 that is present therebetween has fluidity and the filling amount that are similar to those between the small panel-side terminal 29 and the small flexible board-side terminal 31. The anisotropic conductive film 19 between the large panel-side terminal 28 and the large flexible board-side terminal 30 has evenness in fluidity and the filling amount, and connection reliability is improved. The large flexible board-side terminal 30 that is relatively thicker than the large panel-side terminal 28 is configured in a separated structure. Therefore, the greater amount of anisotropic conductive film 19 can be moved to a space between the adjacent separated large flexible board-side terminals 30a in executing the mounting process of the flexible printed circuit board 13. Namely, the fluidity of the anisotropic conductive film 19 is improved and the filling amount of the anisotropic conductive film 19 can be appropriately equalized, and the connection reliability is further improved.

As illustrated in FIG. 8, each separated large flexible board-side terminal 30a of the large flexible board-side terminal 30 includes a basal end side portion (a current supply source side portion, an upstream side portion) 30a1 and a distal end side portion (a current supplied side portion, a lower stream side portion) 30a2. The distal end side portion 30a2 has a width relatively larger than that of the basal end side portion 30a1. Each separated large flexible board-side terminal 30a has a portion other than the distal end side portion 30a2 (including the basal end side portion 30a1) and the portion has a width that is constant and substantially equal to that of the small flexible board-side terminal 31. Each separated large flexible board-side terminal 30a has the distal end side portion 30a2 that is formed in a step-like shape having a greater width than the other portion. As described before, the large flexible board-side terminal 30 has electric resistance lower than that of the large panel-side terminal 28 that is to be connected. Therefore, the amount of the current flowing from the large flexible board-side terminal 30 toward the large panel-side terminal 28 is greater at the distal end side portion 30a2 than the basal end side portion 30a1 of each of the separated large flexible board-side terminal 30a of the large flexible board-side terminal 30. As described before, the distal end side portion 30a2 of the separated large flexible board-side terminal 30a of the large flexible board-side terminal 30 having a greater amount of current flow is relatively wider than the basal end side portion 30a1. Therefore, a current flows effectively between the large terminals 28, 30 and effective electric resistance related to the connection is decreased. Accordingly, driving power and a ground potential can be transferred between the large terminals 28, 30 with lower loss even if the liquid crystal panel 11 is progressed in high precision, high function, and high speed operation. The large flexible board-side terminals 30 and the small flexible board-side terminals 31 are illustrated with a cross sectional view in FIG. 8 for easy understanding.

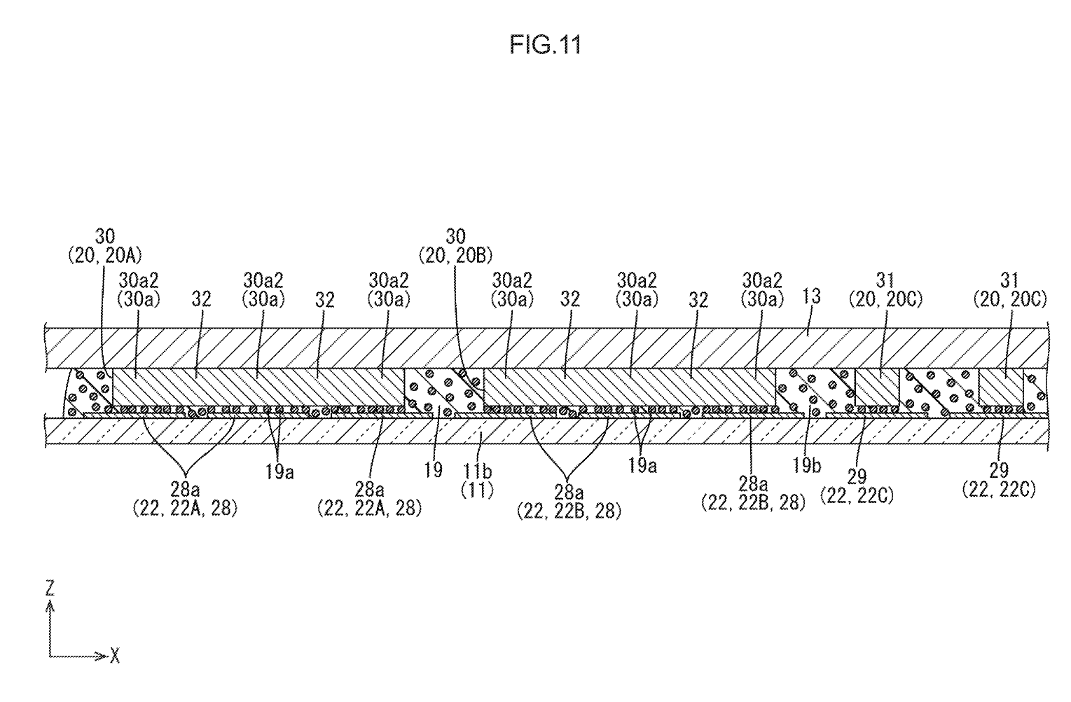

Furthermore, as illustrated in FIGS. 8 and 11, the large flexible board-side terminal 30 includes a terminal connection portion 32 that connects the distal end side portions 30a2 of the adjacent separated large flexible board-side terminals 30a. Thus, the distal end side portions 30a2 of the adjacent separated large flexible board-side terminals 30a are connected to each other by the terminal connection portion 32. According to such a configuration, the distal end side portion 30a2 of the separated large flexible board-side terminal 30a with respect to the basal end side portion 30a1, that is a portion through which a greater amount of current flows, has a width that is increased at most such that the effective electric resistance related to the connection can be further decreased. The terminal connection portion 32 connects distal end portions 30a3 of the distal end side portions 30a2 of the adjacent separated large flexible board-side terminals 30a. The current amount is greatest at the distal end portion 30a3 of the distal end side portion 30a2 of the separated large flexible board-side terminal 30a and the distal end portions 30a3 having the greatest current amount are connected by the terminal connection portion 32 such that the effective electric resistance related to the connection can be further decreased.

As described before, the terminal connection structure of the liquid crystal panel (the display panel) 11 and the flexible printed circuit board (the mounting component) 13 according to this embodiment includes the large panel-side terminals (high resistance terminals) 28 having relatively high electric resistance, and the large flexible board-side terminals (low resistance terminals) 30 that are connected to the large panel-side terminals 28 and have relatively low electric resistance. The large flexible board-side terminal 30 includes at least the separated large flexible board-side terminals (separated low resistance terminals) 30a that are arranged at intervals. The separated large flexible board-side terminal 30a includes the distal end side portion 30a2 having a relatively greater width with respect to the basal end side potion 30a1.

According to such a configuration, if the large panel-side terminal 28 is connected to the separated large flexible board-side terminals 30a of the large flexible board-side terminal 30, a current that is supplied to one of the large panel-side terminal 28 and the large flexible board-side terminal 30 flows to the other one of them. With the large flexible board-side terminal 30 including the separated large flexible board-side terminals 30a, the connection reliability is higher compared to a known configuration that the pad and the terminal that are connected to each other are not separated.

A current flowing between the large panel-side terminal 28 and the large flexible board-side terminal 30 tends to flow through the large flexible board-side terminal 30, which has relatively low electric resistance, for a longer time as possible. Specifically, if a current flows from the large flexible board-side terminal 30 side to the large panel-side terminal 28 side, the current amount flowing from the distal end side portion 30a2 of the large flexible board-side terminal 30 to the large panel-side terminal 28 is greater than the current amount flowing from the basal end side portion 30a1 to the large panel-side terminal 28. If a current flows from the large panel-side terminal 28 side to the large flexible board-side terminal 30 side, the current amount flowing from the basal end side portion 30a1 in the large panel-side terminal 28 to the large flexible board-side terminal 30 is greater than the current amount flowing from the distal end side portion 30a2 in the large panel-side terminal 28. The distal end side portion 30a2 of each of the separated large flexible board-side terminals 30a of the large flexible board-side terminal 30 has a relatively greater width with respect to the basal end side potion 30a1, and namely, the distal end side portion 30a2 through which a greater amount of current flows has a relatively greater width. According to such a configuration, a current efficiently flows between the terminals 28, 30 and effective electric resistance related to the connection can be lowered. Accordingly, the connection reliability can be kept high and effective electric resistance related to the connection can be lowered.

The large flexible board-side terminal 30 includes the terminal connection portion 32 that connects the distal end side portions 30a2 of the adjacent separated large flexible board-side terminals 30a. Thus, the distal end side portions 30a2 of the adjacent separated large flexible board-side terminals 30a are connected to each other by the terminal connection portion 32. According to such a configuration, the distal end side portion 30a2 of the separated large flexible board-side terminal 30a with respect to the basal end side portion 30a1, that is a portion through which a greater amount of current flows, has a width that is increased at most such that the effective electric resistance related to the connection can be further lowered.

The terminal connection portion 32 connects the distal end portions 30a3 of the distal end side portions 30a2 of the adjacent separated large flexible board-side terminals 30a. The current amount is greatest at the distal end portion 30a3 of the distal end side portion 30a2 of the separated large flexible board-side terminal 30a and the distal end portions 30a3 having the greatest current amount are connected by the terminal connection portion 32 such that the effective electric resistance related to the connection can be further lowered.

The large flexible board-side terminal 30 is relatively thicker than the large panel-side terminal 28. According to such a configuration, the electric resistance of the large flexible board-side terminal 30 is preferably lowered. The large flexible board-side terminal 30 that is relatively thick includes the separated large flexible board-side terminals 30a. With such a configuration, the connection reliability is further improved compared to a configuration that only a relatively thin large panel-side terminal has a separated structure.

The terminal connection structure further includes the small panel-side terminals (the second high resistance terminals) 29 and the small flexible board-side terminals (the second low resistance terminals) 31. The small panel-side terminals 29 are arranged adjacent to the large panel-side terminal 28 and the small flexible board-side terminals 31 are arranged adjacent to the large flexible board-side terminal 30. Each of the small flexible board-side terminals 31 has a width equal to that of the separated large flexible board-side terminal 30a and is connected to the small panel-side terminal 29. According to such a configuration, the separated large flexible board-side terminal 30a and small flexible board-side terminal 31 have a same width. Therefore, the separated large flexible board-side terminals 30a and small flexible board-side terminals 31 can be collectively connected to the large panel-side terminals 28 and the small panel-side terminals 29 and high connection reliability can be obtained.

Furthermore, the terminal connection structure of the liquid crystal panel 11 and the flexible printed circuit board 13 of this embodiment includes the large panel-side terminal 28 having relatively high electric resistance and the large flexible board-side terminal 30 having relatively low electric resistance. The large panel-side terminal 28 includes at least the separated large panel-side terminals (separated high resistance terminals) 28a that are arranged at intervals. The large flexible board-side terminal 30 includes at least the separated large flexible board-side terminals 30a that are connected to the separated large panel-side terminals 28a and arranged at intervals. One of the width of the distal end side portion 30a2 in the separated large flexible board-side terminals 30a with respect to the basal end side portion 30a1 and the width of the basal end side portion 30a1 in the separated large panel-side terminals 28a with respect to the distal end side portion 30a2 is relatively greater.

According to such a configuration, if the separated large panel-side terminals 28a of the large panel-side terminal 28 are connected to the separated large flexible board-side terminals 30a of the large flexible board-side terminal 30, a current that is supplied to one of the large panel-side terminal 28 and the large flexible board-side terminal 30 flows to the other one of them. With the configuration of the large panel-side terminal 28 including the separated large panel-side terminals 28a and the large flexible board-side terminal 30 including the separated large flexible board-side terminals 30a, the connection reliability is higher compared to a known configuration that the pad and the terminal that are connected to each other are not separated.

A current flowing between the large panel-side terminal 28 and the large flexible board-side terminal 30 tends to flow through the large flexible board-side terminal 30, which has relatively low electric resistance, for a longer time as possible. Specifically, if a current flows from the large flexible board-side terminal 30 side to the large panel-side terminal 28 side, the current amount flowing from the distal end side portion 30a2 of the large flexible board-side terminal 30 to the large panel-side terminal 28 is greater than the current amount flowing from the basal end side portion 30a1 to the large panel-side terminal 28. If a current flows from the large panel-side terminal 28 side to the large flexible board-side terminal 30 side, the current amount flowing from the basal end side portion 30a1 of the large panel-side terminal 28 to the large flexible board-side terminal 30 is greater than the current amount flowing from the distal end side portion 30a2 to the large flexible board-side terminal 30. One of the width of the distal end side portion 30a2 of the separated large flexible board-side terminals 30a of the large flexible board-side terminal 30 with respect to the basal end side potion 30a1 and the width of the basal end side portion 30a1 of the separated large panel-side terminals 28a of the large panel-side terminal 28 with respect to the distal end side portion 30a2 is relatively larger. Namely, one of the portions through which greater amount of current flows has a relatively larger width. According to such a configuration, a current efficiently flows between the terminals 28, 30 and effective electric resistance related to the connection can be lowered. Accordingly, the connection reliability can be kept high and effective electric resistance related to the connection can be lowered.

The liquid crystal display device (the display device) 10 according to this embodiment includes the above-described terminal connection structure, the liquid crystal panel (the display panel) 11 including the large panel-side terminals 28, and the flexible printed circuit board (the mounting component) 13 including the large flexible board-side terminals 30 and mounted on the liquid crystal panel 11. According to the liquid crystal display device 10 having such a configuration, the connection reliability of the flexible printed circuit board 13 to the liquid crystal panel 11 is high and the connection resistance is lowered such that high display quality can be stably obtained.

### Second Embodiment

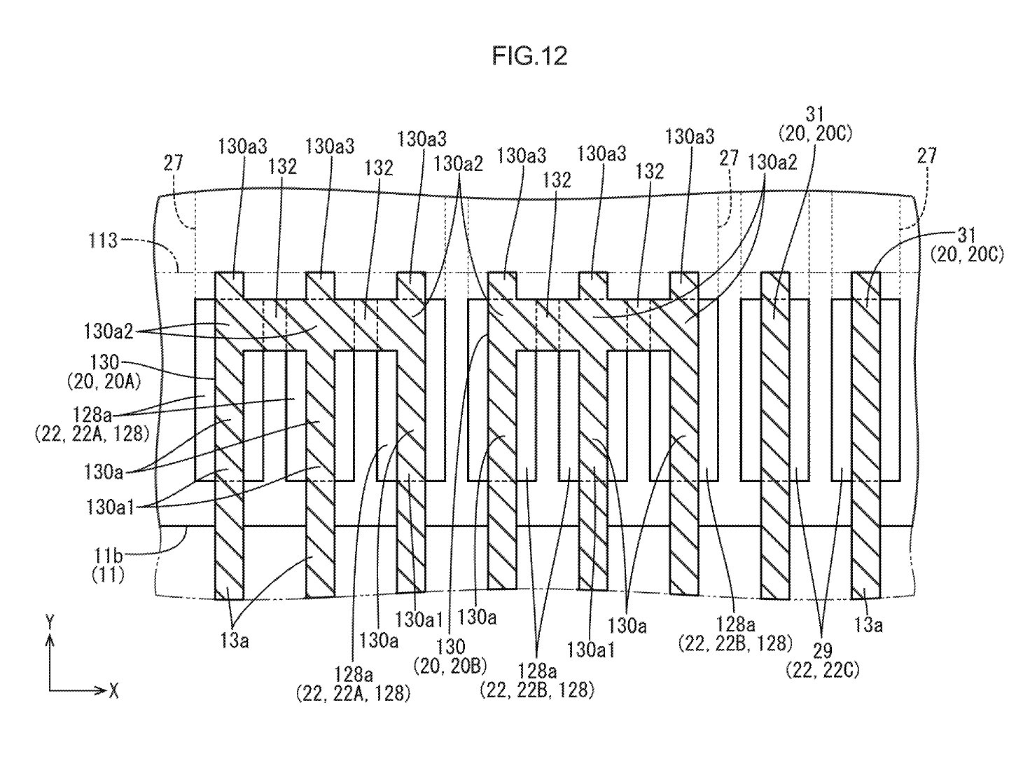

A second embodiment of the present invention will be described with reference to FIG. 12. Configurations, operations, and effects similar to those of the first embodiment will not be described.

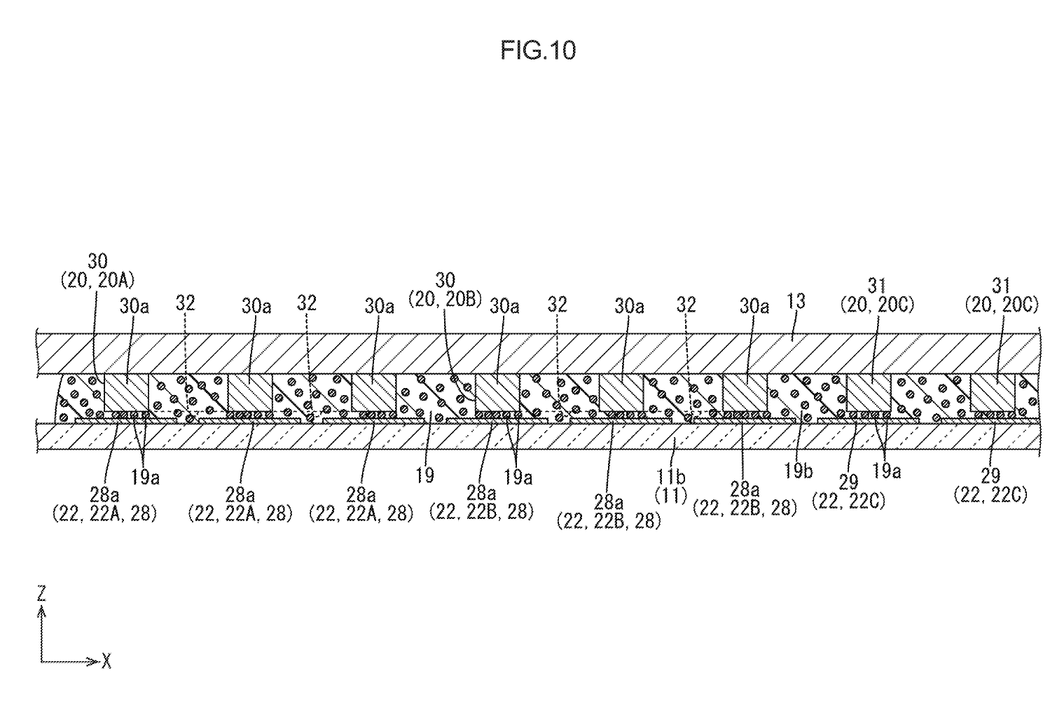

As illustrated in FIG. 10, a terminal connection portion 132 according to this embodiment connects portions of distal end side portions 130a2 of adjacent separated large flexible board-side terminals 130a of the large flexible board-side terminals 130 and the connected portions of the distal end side portions 130a2 are closer to basal ends (closer to a signal supply source, closer to an upstream side) than distal end portions 130a3. The distal end portion 130a3 of the distal end side portion 130a2 of each separated large flexible board-side terminal 130a has a width substantially equal to that of the basal end side portion 130a1 and is not a large width portion. Namely, the distal end side portion 130a2 of each separated large flexible board-side terminal 130a partially has a large width. The distal end portion 130a3 of the distal end side portion 130a2 of each separated large flexible board-side terminal 130a projects toward the distal end side (toward the signal supplied side, toward the lower stream side) from the terminal connection portion 132. A projection dimension of the distal end portion 130a3 is substantially equal to a largest value of a position error amount of a flexible printed circuit board 113 and a liquid crystal panel 111 in the Y-axis direction that may be caused when mounting the flexible printed circuit board 113 in the liquid crystal panel 111. Specifically, the projection dimension may be approximately 50 μm to 100 μm. According to such a configuration, the distal end portion 130a3 of the distal end side portion 130a2 of each separated large flexible board-side terminal 130a may not contribute to the connection to separated large panel-side terminals 128a if the flexible printed circuit board 113 is appropriately mounted on the liquid crystal panel 111. In such a case, the terminal connection portion 132 connects the portions of the distal end side portions 130a2 of the adjacent separated large flexible board-side terminals 130a and the connected portions of the distal end side portions 130a2 are closer to the basal ends than the distal end portions 130a3, and effective electric resistance can be lowered.

As described before, according to this embodiment, the terminal connection portion 132 connects the portions of the distal end side portions 130a2 of the adjacent separated large flexible board-side terminals 130a and the portions of the distal end side portions 130a2 are closer to the basal ends than the distal end portions 130a3. A positioning error may be caused in the connection of the large panel-side terminals 128 and the separated large flexible board-side terminals 130a. In some cases, the distal end portion 130a3 of the distal end side portion 130a2 of the separated large flexible board-side terminal 130a may not contribute to the connection to the large panel-side terminals 128. Even in such a case, the terminal connection portion 132 connects the portions of the distal end side portions 130a2 of the adjacent separated large flexible board-side terminals 130a and the portions of the distal end side portions 130a2 are closer to the basal ends than the distal end portions 130a3, and according to such a configuration, effective electric resistance can be lowered.

### Third Embodiment

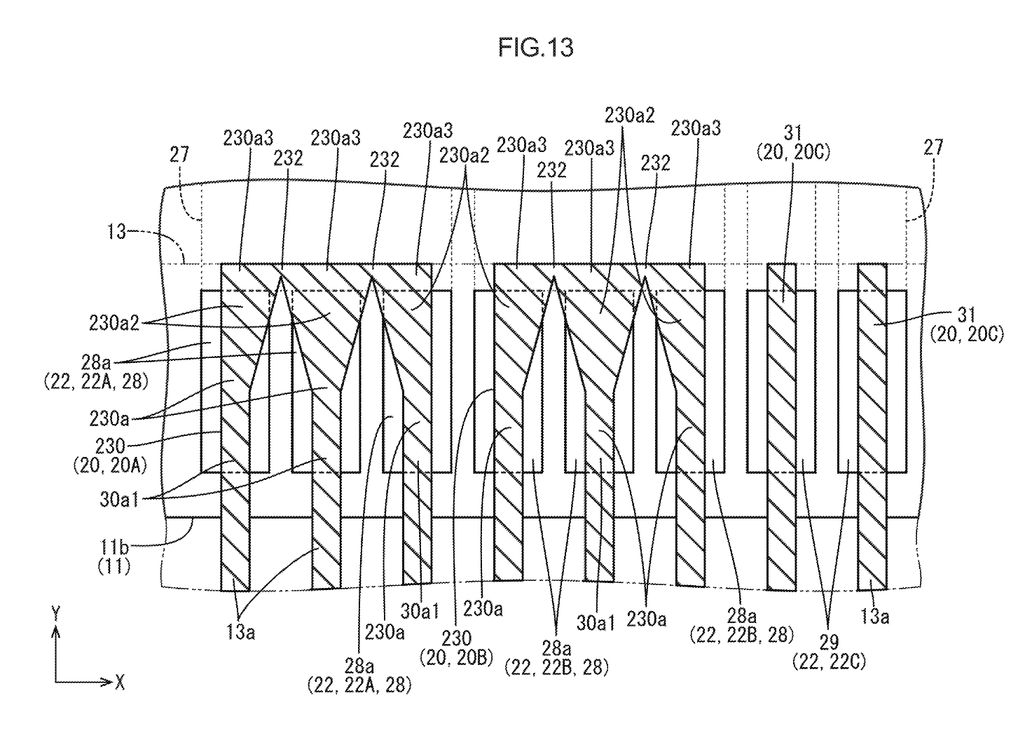

A third embodiment of the present invention will be described with reference to FIG. 13. In the third embodiment, a shape of a distal end side portion 230a2 of a separated large flexible board-side terminal 230a is altered from that of the first embodiment. Configurations, operations, and effects similar to those of the first embodiment will not be described.

As illustrated in FIG. 13, a large flexible board-side terminal 230 of this embodiment includes separated large flexible board-side terminals 230a each having a width that increases from a basal end side toward a distal end side. More in detail, the large flexible board-side terminal 230 includes three separated large flexible board-side terminals 230a. Two of the three separated large flexible board-side terminals 230a that are included at two edges in an arrangement direction (the X-axis direction) include the distal end side portions 230a2 each of which increases its width from the basal end side toward the distal end side so as to be closer to the separated large flexible board-side terminal 230a on the middle. The separated large flexible board-side terminal 230a on the middle with respect to the arrangement direction includes the distal end side portion 230a2 that increases its width from the basal end side toward the distal end side so as to be closer to the respective two separated large flexible board-side terminals 230a. The distal end side portion 230a2 of each separated large flexible board-side terminal 230a increases its width and edges thereof are inclined with respect to the X-axis direction and the Y-axis direction and a wide portion has a triangular plan view shape. At the distal end side portions 230a2 of the separated large flexible board-side terminals 230a, the distal end portions 230a3 are connected to each other by a terminal connection portion 232. Thus, the width of the distal end side portion 230a2 of each separated large flexible board-side terminal 230a increases from the basal end side toward the distal end side or toward the portion having a greater amount of current. Therefore, effective electric resistance related to the connection can be further lowered. An area of the wide portion of the distal end side portion 230a2 of each separated large flexible board-side terminal 230a with respect to the Y-axis direction is greater than that of the first embodiment.

As described before, according to this embodiment, the separated large flexible board-side terminals 230a include the distal end side portions 230a2 having a width increasing from the basal end side toward the distal end side. The width of the distal end side portions 230a2 of the separated large flexible board-side terminals 230a increases from the basal end side toward the distal end side or toward the portion having a greater amount of current flow. Therefore, effective electric resistance related to the connection can be further lowered.

### Fourth Embodiment

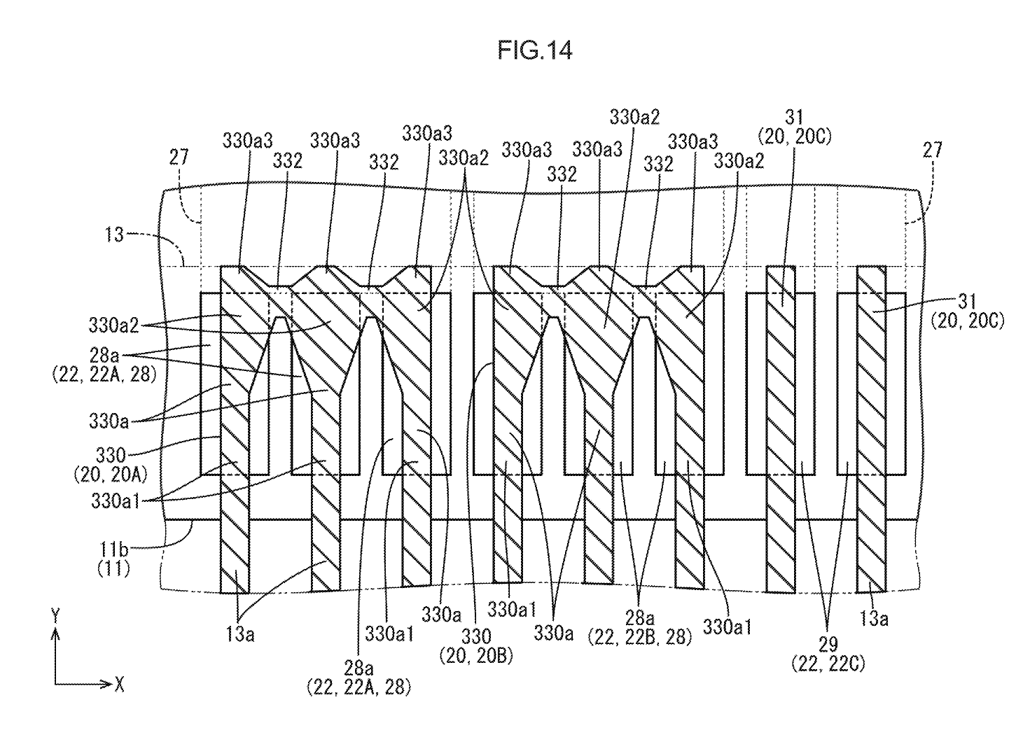

A fourth embodiment of the present invention will be described with reference to FIG. 14. In the fourth embodiment, an arrangement of a terminal connection portion 332 is altered from that of the third embodiment similarly to the second embodiment. Configurations, operations, and effects similar to those of the second and third embodiments will not be described.

As illustrated in FIG. 14, the terminal connection portion 332 of this embodiment connects portions of distal end side portions 330a2 of adjacent separated large flexible board-side terminals 330a of large flexible board-side terminals 330. Each of the connected portions of the distal end side portions 330a2 is closer to a basal end than a distal end portion 330a3. The distal end portion 330a3 of the distal end side portion 330a2 of each separated large flexible board-side terminal 330a has a width larger than a width of a basal end side portion 330a1. Namely, the width of the distal end side portion 330a2 of each separated large flexible board-side terminal 330a is larger than that of the basal end side portion 330a1 over an entire area thereof.

### Fifth Embodiment

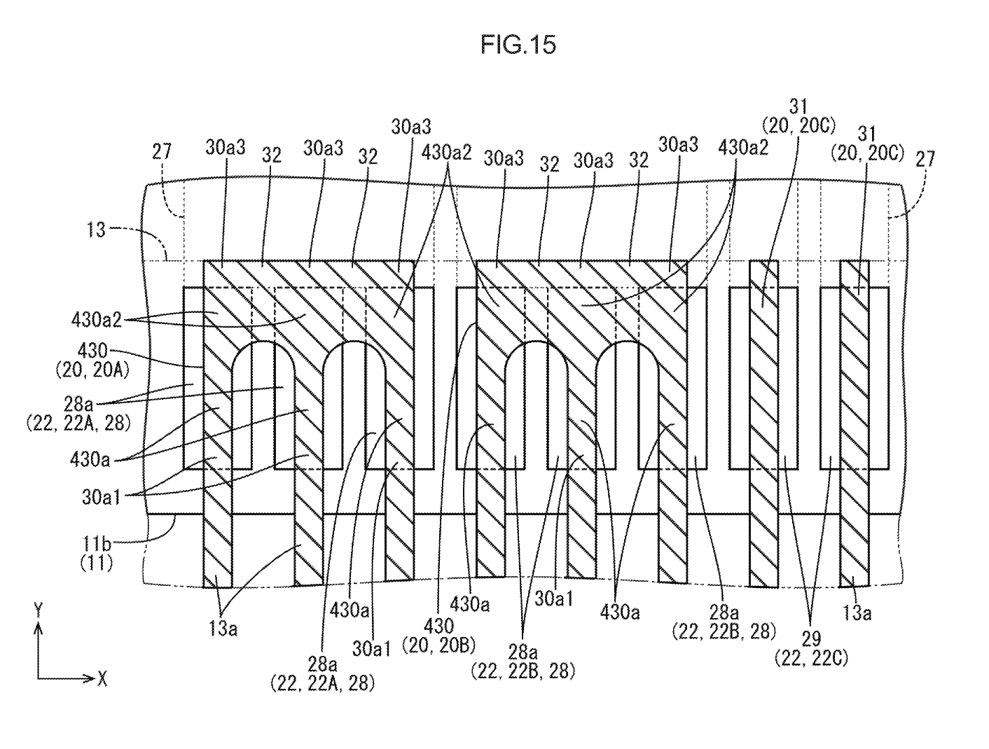

A fifth embodiment of the present invention will be described with reference to FIG. 15. In the fifth embodiment, a shape of a distal end side portion 430a2 of a separated large flexible board-side terminal 430a is altered from that of the first embodiment. Configurations, operations, and effects similar to those of the first embodiment will not be described.

As illustrated in FIG. 15, a large flexible board-side terminal 430 includes separated large flexible board-side terminals 430a each having a distal end side portion 430a2. The distal end side portion 430a2 increases its width in an arched shape from a basal end side toward a distal end side.

### Sixth Embodiment

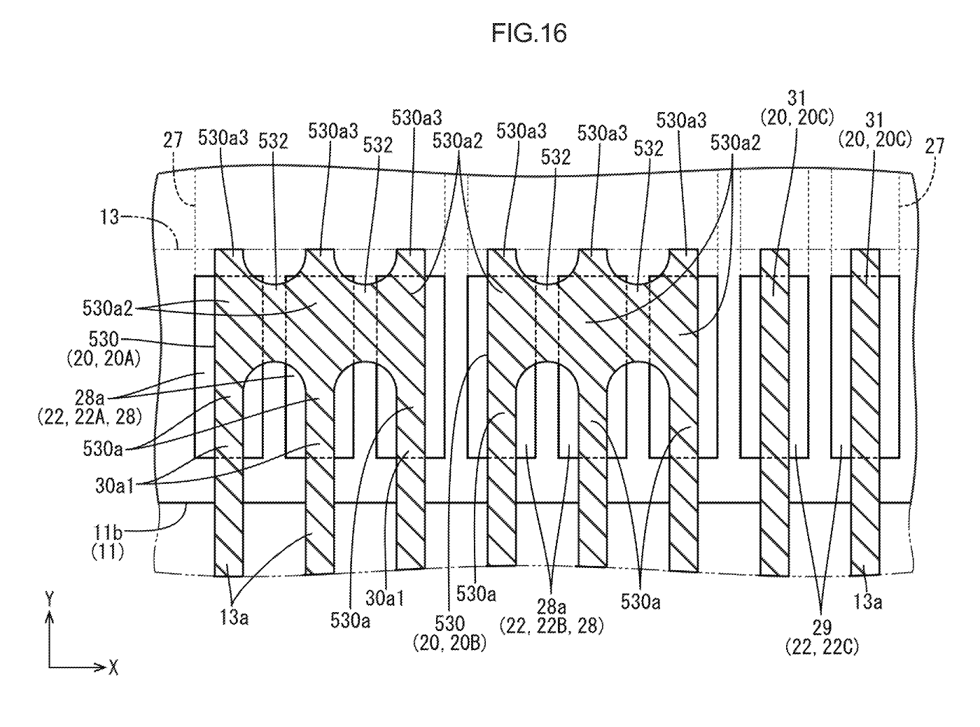

A sixth embodiment of the present invention will be described with reference to FIG. 16. In the sixth embodiment, an arrangement of a terminal connection portion 532 is altered from that of the fifth embodiment similarly to the second embodiment. Configurations, operations, and effects similar to those of the second and fifth embodiments will not be described.

As illustrated in FIG. 16, a large flexible board-side terminal 530 includes separated large flexible board-side terminals 530a each having a distal end side portion 530a2. The distal end side portion 530a2 increases its width in an arched shape from a basal end side toward a distal end side. Furthermore, a terminal connection portion 532 connects portions of the distal end side portions 530a2 that are closer to the basal ends than distal end portions 530a3.

### Seventh Embodiment

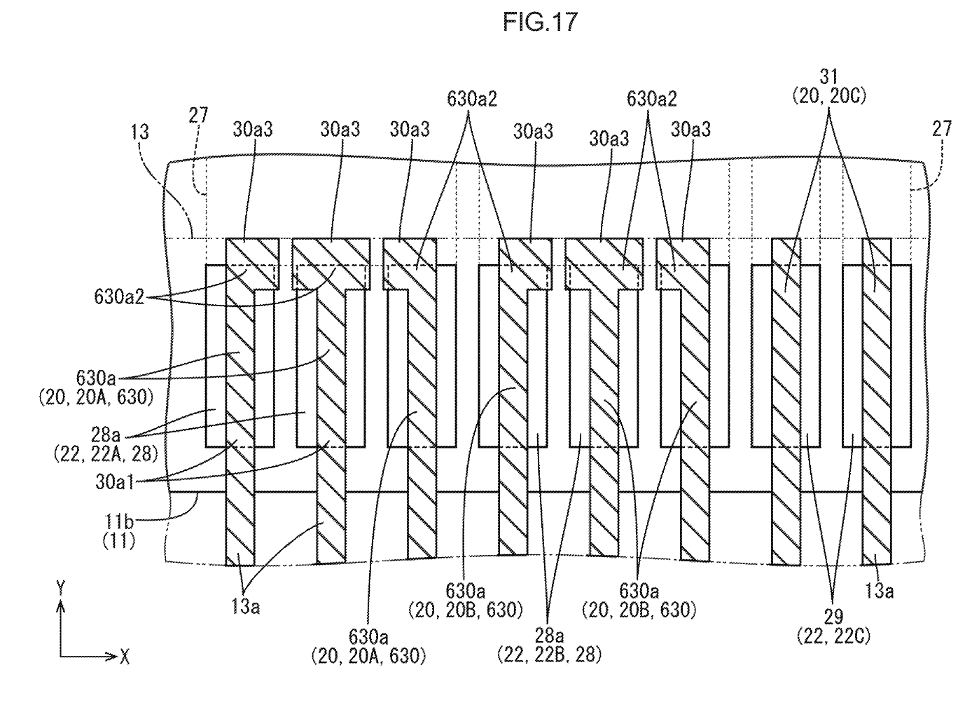

A seventh embodiment of the present invention will be described with reference to FIG. 17. In the seventh embodiment, a shape of a large flexible board-side terminal 630 is altered from that of the first embodiment. Configurations, operations, and effects similar to those of the first embodiment will not be described.

As illustrated in FIG. 17, in the large flexible board-side terminal 630, distal end side portions 630a2 of adjacent separated large flexible board-side terminals 630a are not connected to each other. Namely, the separated large flexible board-side terminals 630a are separated from each other. In such a configuration, a distal end side portion 630a2 of each of the separated large flexible board-side terminals 630a has a larger width. Therefore, effective electric resistance can be lowered.

### Eighth Embodiment

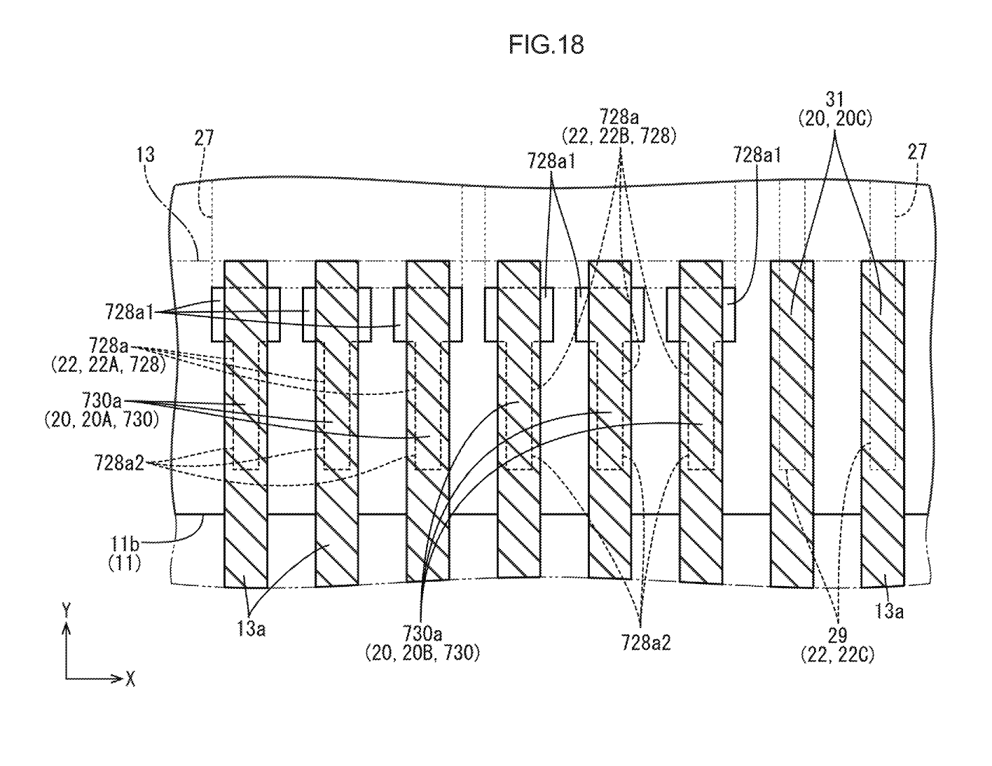

An eighth embodiment of the present invention will be described with reference to FIG. 18. In the eighth embodiment, a shape of a large panel-side terminal 728 and a shape of a large flexible board-side terminal 730 are altered from those of the first embodiment. Configurations, operations, and effects similar to those of the first embodiment will not be described.

As illustrated in FIG. 18, the large flexible board-side terminal 730 of this embodiment includes separated large flexible board-side terminals 730a and a width of each separated large flexible board-side terminal 730a is constant over an entire length thereof. The separated large flexible board-side terminals 730a are not connected to each other and are separated from each other. The large panel-side terminal 728 includes separated large panel-side terminals 728a each including a basal end side portion 728a1 and a distal end side portion 728a2. A width of the basal end side portion 728a1 is greater than that of the distal end side portion 728a2. Specifically, most portion of each separated large panel-side terminal 728a other than the basal end side portion 728a1 (including the distal end side portion 728a2) has a width that is smaller than a width of each separated large flexible board-side terminal 730a, and a width of the basal end side portion 728a1 is larger than that of each separated large flexible board-side terminal 730a. As described before, the large flexible board-side terminal 730 has electric resistance lower than that of the large panel-side terminal 728 that is to be connected to. With the above configuration, similar to the first embodiment, in a configuration that a current flows from the large flexible board-side terminal 730 side to the large panel-side terminal 728 side, the current amount flowing from each separated large flexible board-side terminal 730a of the large flexible board-side terminal 730 to the basal end side portion 728a1 is greater than the current amount flowing from, each separated large flexible board-side terminal 730a to the distal end side portion 728a2. The basal end side portion 728a1 of each separated large panel-side terminal 728a has a relatively larger width with respect to the distal end side portion 728a2, that is, the portion of each separated large panel-side terminal 728a through which a greater amount of current flows has a relatively larger width. Accordingly, a current effectively flows between the large terminals 728, 730 and effective electric resistance related to the connection is lowered.

### Ninth Embodiment

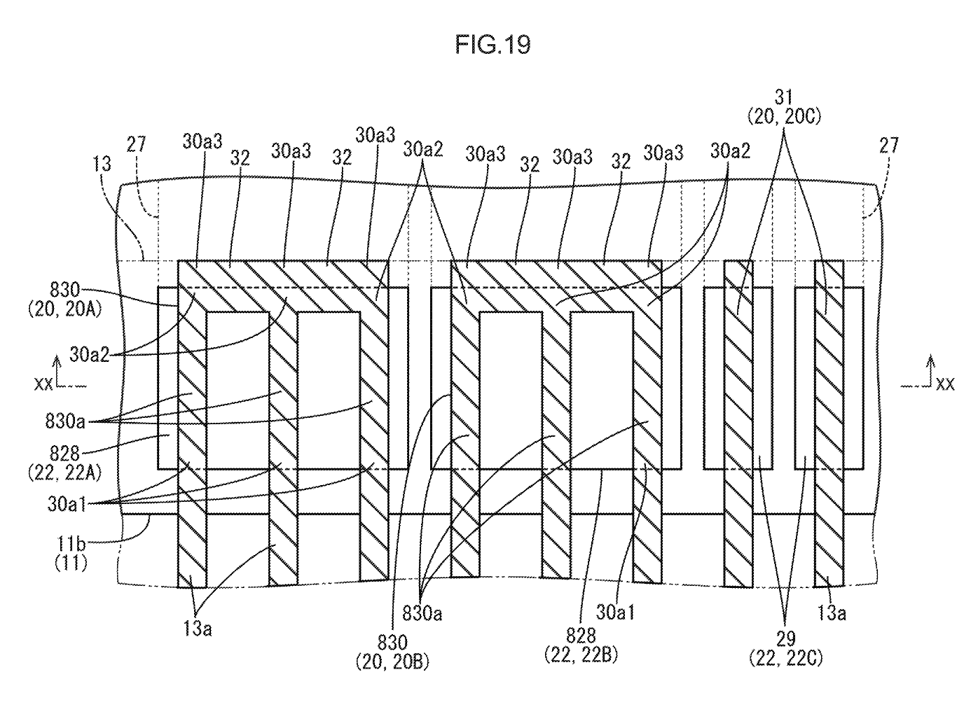

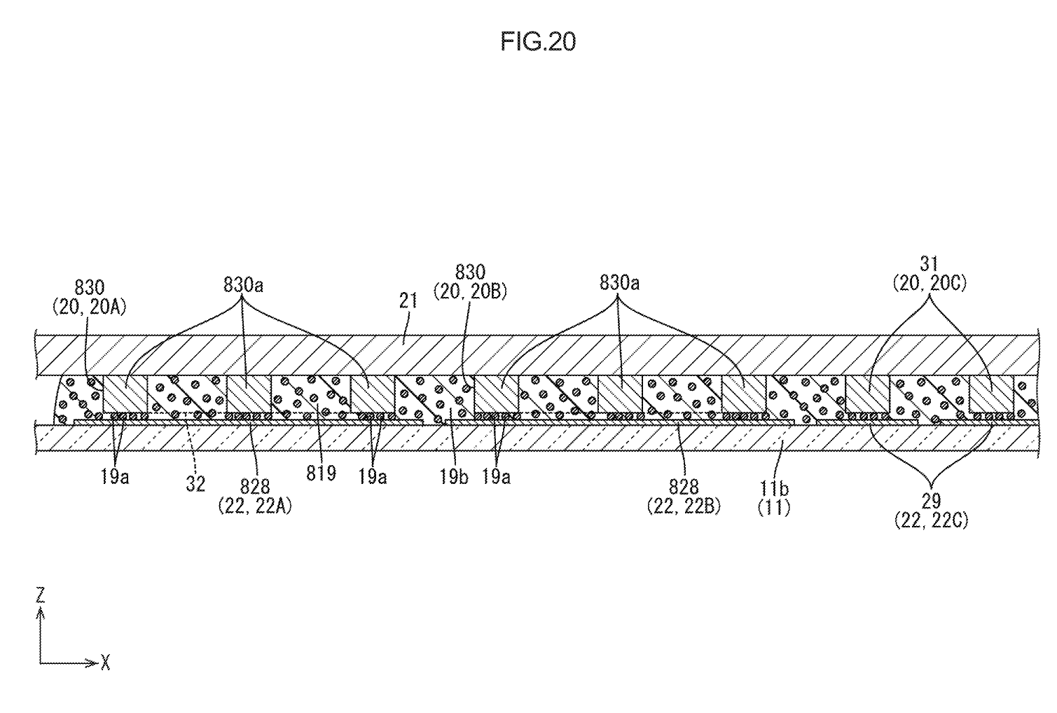

A ninth embodiment of the present invention will be described with reference to FIGS. 19 and 20. In the ninth embodiment, a configuration of a large panel-side terminal 828 is altered from that of the first embodiment. Configurations, operations, and effects similar to those of the first embodiment will not be described.

As illustrated in FIGS. 19 and 20, the large panel-side terminal 828 has a non-separated structure and is not separated into pieces. The large panel-side terminal 828 has a width greater than a width of a large flexible board-side terminal 830 and is connected to three separated large flexible board-side terminals 830a of the large flexible board-side terminal 830. As described in the first embodiment, a thickness of the large panel-side terminal 828 is quite smaller than that of the large flexible board-side terminal 830. Therefore, even with the non-separated configuration of the large panel-side terminal 828, unevenness in fluidity and the filling amount is less likely to be caused in an anisotropic conductive film 819. In other words, the large flexible board-side terminal 830 having a great thickness is configured in a separated configuration and evenness in fluidity and the filling amount in the anisotropic conductive film 819 can be achieved and good connection reliability can be obtained.

### Other Embodiments

The present invention is not limited to the embodiments, which have been described using the foregoing descriptions and the drawings. For example, embodiments described below are also included in the technical scope of the present invention.

(1) In each of the above embodiments (except for the eighth embodiment), the width of the separated flexible board-side terminal of the large flexible board-side terminal is smaller than that of the separated panel-side terminal of the large panel-side terminal. However, the width of the separated flexible board-side terminal of the large flexible board-side terminal may be larger than that of the separated panel-side terminal of the large panel-side terminal. The width of the separated flexible board-side terminal of the large flexible board-side terminal may be equal to that of the separated panel-side terminal of the large panel-side terminal.

(2) In each of the above embodiments, the electric resistance of the large panel-side terminal is relatively high and the electric resistance of the large flexible board-side terminal is relatively low. However, the electric resistance of the large panel-side terminal may be relatively low and the electric resistance of the large flexible board-side terminal may be relatively high. In this configuration, a width of the distal end side portion of the separated large panel-side terminal of the large panel-side terminal may be relatively large with respect to the basal end side portion. A width of the basal end side portion of the separated large flexible board-side terminal of the large flexible board-side terminal may be relatively large with respect to the distal end side portion.

(3) In each of the above embodiments, on the flexible printed circuit board, the width of the trace pattern that is connected to the large flexible board-side terminal is equal to that of the separated flexible board-side terminal. However, the width of the trace pattern may be equal to that of the large flexible board-side terminal and may be continuous to each of the separated flexible board-side terminals.

(4) in each of the above embodiments, the large flexible board-side terminal is separated into three separated large flexible board-side terminals. However, the number of separation of the large flexible board-side terminal may be two, four or more.

(5) In the first to eighth embodiments, the large panel-side terminal is separated into three separated large panel-side terminals. However, the number of separation of the large panel-side terminal may be two, four or more.

(6) In each of the above embodiments, a pair of the power source flexible board-side terminal and the power source panel-side terminal and a pair of ground flexible board-side terminal and the ground panel-side terminal are included. However, multiple pairs of them may be included.

(7) In each of the above embodiments, the terminal connection structure of the liquid crystal panel and the flexible printed circuit board is described. However, the present invention may be applied to a terminal connection structure of a liquid crystal panel and a driver. Furthermore, the present invention may be applied to a terminal connection structure of a printed wiring board (such as a control circuit board) and a flexible printed circuit board.

(8) In each of the above embodiments, the driver is mounted on the array substrate of the liquid crystal panel with a COG technology. The driver may be mounted on the flexible printed circuit board with a Chip on Film (COF) technology. In such a configuration, the present technology may be applied to a terminal connection structure of the liquid crystal panel and the flexible printed circuit board and also may be applied to a terminal connection structure of the flexible printed circuit board and the driver.

(9) Other than the configuration of each of the embodiments illustrated in the drawings, a ratio of a connection area with the terminal connection portion and an entire length of each separated flexible board-side terminal may be altered appropriately.

(10) In each of the above embodiments, the material of each terminal of the flexible printed circuit board and the material of each terminal of the liquid crystal panel are different from each other but may be same. In such a configuration, the large flexible board-side terminal and the large panel-side terminal are configured to have different electric resistance by providing different dimensions in one of a width dimension or a thickness dimension.

(11) In each of the above embodiments, the width and the thickness of each separated large flexible board-side terminal of the large flexible board-side terminal are different from those of each separated large panel-side terminal of the large panel-side terminal. However, they may be same and in such a configuration, the large flexible board-side terminal and the large panel-side terminal may be made of different material to provide different electric resistance.

(12) Other than each of the above embodiments, the material of each terminal may be altered appropriately. Specifically, material of each terminal may be titanium, tungsten, silver, gold, or others.

(13) In the second, fourth, and sixth embodiments, a whole distal end portion of each separated flexible board-side terminal remains. However, a part of the distal end portion of each separated flexible board-side terminal may be removed.

(14) In the third and fourth embodiments, the distal end side portion of each separated flexible board-side terminal has a sloped side edge in a plan view. However, the side edge may have a step-like shape.

(15) In each of the third and fourth embodiments, the sloped side edge of the distal end side portion of each separated flexible board-side terminal has a constant inclination angle. However, the inclination angle of the sloped side edge may be changed in a middle thereof.

(16) In each of the fifth and sixth embodiments, the distal end side portion of each separated flexible board-side terminal has an side edge having a semicircular plan view shape. However, the side edge may have a semi-elliptical shape.

(17) In a modified embodiment of the eighth embodiment, in the large panel-side terminal, the basal end side portions of the adjacent separated large panel-side terminals may be connected to each other by a terminal connection portion.

(18) The configurations of the second and third embodiments may be combined. In such a configuration, in the distal end side portion of each separated flexible board-side terminal, a distal end portion may have a constant width and a side edge on the basal end side may have a sloped plan view shape.

(19) The configurations of the second and fourth embodiments may be combined. In such a configuration, in the distal end side portion of each separated flexible board-side terminal, a side edge on the distal end side may have a sloped plan view shape and a basal end portion may have a constant width.

(20) The configurations of the second and fifth embodiments may be combined. In such a configuration, in the distal end side portion of each separated flexible board-side terminal, a distal end portion may have a constant width and a side edge on the basal end side may have a semicircular shape.

(21) The configurations of the second and sixth embodiments may be combined. In such a configuration, in the distal end side portion of each separated flexible board-side terminal, a side edge on the distal end side may have an arched plan view shape and a basal end portion may have a constant width.

(22) The configurations of the seventh to ninth embodiments may be appropriately combined with the configurations of the second to sixth embodiments.

(23) In each of the above embodiments, the liquid crystal panel includes the color filter of three colors including red, green, and blue. However, the present invention may be applied to the configuration including the color filter of four colors including a yellow color portion in addition to the color portions of red, green, and blue.

(24) In each of the above embodiments, the liquid crystal panel including a pair of substrates and the liquid crystal layer sandwiched therebetween is described. However, the present invention may be applied to a display panel including a pair of substrates and functional organic molecules other than the liquid crystal material held therebetween.

(25) In each of the above embodiments, the TFTs are used as switching components of the liquid crystal panel. However, switching components other than the TFTs (such as thin film diodes (TFDs)) may be included in the scope of the present invention. Furthermore, a liquid crystal panel configured to display black and white images other than the liquid crystal panel configured to display color images.

(26) In each of the above embodiments, the liquid crystal panel is described as the display panel. However, the present invention may be applied to other kinds of display panels (such as plasma display panel (PDP), an organic EL panel, an electrophoretic display panel (EPD), and a micro electro mechanical system (MEMS) display panel).

### EXPLANATION OF SYMBOLS

10: liquid crystal display device (display device), 11, 111: liquid crystal panel (display panel), 13: flexible printed circuit board (mounting component), 28, 128, 728, 828: large panel-side terminal (high resistance terminal), 28a, 128a, 728a: separated large panel-side terminal (separated high resistance terminal), 29: small panel-side terminal (second high resistance terminal), 30, 130, 230, 330, 430, 530, 630, 730, 830: large flexible board-side terminal (low resistance terminal), 30a, 130a, 330a, 430a, 530a, 630a, 730a, 830a: separated large flexible board-side terminal (separated low resistance terminal), 30a1, 130a1, 330a1: basal end side portion, 30a2, 130a2, 230a2, 330a2, 430a2, 530a2, 630a2: distal end side portion, 30a3, 130a3, 230a3, 330a3, 530a3: distal end portion, 31: small flexible board-side terminal (second low resistance terminal), 32, 132, 232, 332, 532: terminal connection portion, 728a1: basal end side portion, 728a2: distal end side portion

1. A terminal connection structure comprising:
a high resistance terminal having relatively high electric resistance; and
a low resistance terminal having relatively low electric resistance and connected to the high resistance terminal, the low resistance terminal including separated low resistance terminals that are arranged at intervals and have a width relatively larger in a distal end side portion with respect to a basal end side portion.

2. The terminal connection structure according to claim 1, wherein the low resistance terminal includes a terminal connection portion that connects distal end side portions of adjacent separated low resistance terminals.

3. The terminal connection structure according to claim 2, wherein the terminal connection portion connects distal end portions of the distal end side portions of the adjacent separated low resistance terminals.

4. The terminal connection structure according to claim 2, wherein the terminal connection portion connects portions of the distal end side portions of the adjacent separated low resistance terminals, and the portions are closer to a basal end side than distal end portions.

5. The terminal connection structure according to claim 1, wherein the distal end side portion of the separated low resistance terminals has a width that increases from a basal end side toward a distal end side.

6. The terminal connection structure according to claim 1, wherein the low resistance terminal is thicker than the high resistance terminal.

7. The terminal connection structure according to claim 1, further comprising:
a second high resistance terminal arranged adjacent to the high resistance terminal; and
a second low resistance terminal arranged adjacent to the low resistance terminal and connected to the second high resistance terminal, the second low resistance terminal having a width same as that of the separated low resistance terminal.

8. A terminal connection structure comprising:
a high resistance terminal having relatively high resistance and including at least separated high resistance terminals arranged at intervals; and
a low resistance terminal having relatively low resistance and including at least separated low resistance terminals that are arranged at intervals and are connected to the separated high resistance terminals, wherein
a width of a distal end side portion of the separated low resistance terminals with respect to a basal end side portion or a width of a basal end side portion of the separated high resistance terminals with respect to a distal end side portion is relatively large.

9. A display device comprising:
the terminal connection structure according to claim 1;
a display panel including the high resistance terminal; and
a mounting component including the low resistance terminal and mounted on the display panel.
